(19) United States
(12) Patent Application Publication
(10) Pub. No.: US 2012/0083196 A1
(43) Pub. Date: Apr. 5, 2012

(54) System and Method for Conditioning Air

(76) Inventor: Peter Leslie Gregory Mockridge, Southwick (GB)

(21) Appl. No.: 12/896,606

(22) Filed: Oct. 1, 2010

(51) Int. Cl. H05K 5/02; F24F 7/007; F24F 11/053

(52) U.S. Cl. 454/184; 454/239; 454/251

(57) ABSTRACT

A technique facilitates the conditioning of air in an equipment room by utilizing external, ambient air and mixing the external air with warmer air from the equipment room to maintain the equipment room within a desired temperature range. In one embodiment, the technique employs an equipment room containing equipment which produces heat. Cool air is routed from an external environment into the equipment room through a cold air duct. Additionally, an exhaust air duct is used to enable the discharge of warm air from the equipment room to the external environment. The temperature of the incoming cool air is adjusted by flowing warm air from the equipment room through a crossover duct able to conduct all or a portion of the airflow routed through the equipment room.

### BACKGROUND

In a variety of cold, e.g. arctic, environments, substantial computing power is required for a variety of applications. For example, large scale computer and instrumentation systems may be employed in arctic environments to facilitate exploration for hydrocarbon bearing formations. However, the computer equipment is designed to operate in an environment maintained within a relatively warm temperature range, such as 20 to 22° C., but the equipment still generates a considerable amount of waste heat during operation. Accordingly, the air must be conditioned for rooms containing the computer equipment.

In warmer climates, a variety of air-conditioning systems may be employed. For example, some systems utilize a heat pump design implemented in traditional air-conditioner systems. However, many difficulties arise in operating such systems in extremely cold climates due to the exposure of a variety of system components to the external air, snow and ice. Sometimes, specially designed and expensive refrigerants, external blowers, heat exchangers and other components may be employed, but these components can be inefficient and add substantial cost to the design. Additionally, such systems become more complex and subject to failure in these cold environments.

### SUMMARY

In general, the present invention provides a system and methodology which efficiently conditions the air in an equipment room by utilizing external, ambient air and mixing the external air with warmer air from the equipment room to maintain the equipment room within a desired temperature range. In one embodiment, the technique employs an equipment room containing equipment which produces heat. Cool air is routed from an external environment into the equipment room through a cold air duct. Additionally, an exhaust air duct is used to enable the discharge of warm air from the equipment room to the external environment. The temperature of the incoming cool air is adjusted by flowing warm air from the equipment room through a crossover duct able to conduct all or a portion of the airflow routed through the equipment room.

### BRIEF DESCRIPTION OF THE DRAWINGS

Certain embodiments of the invention will hereafter be described with reference to the accompanying drawings, wherein like reference numerals denote like elements, and:

FIG. 1 is a schematic illustration of one example of an air conditioning system, according to an embodiment of the present invention;

FIG. 2 is a schematic view illustrating another example of the air conditioning system in a portable format, according to an embodiment of the present invention;

FIG. 3 is a schematic representation of an example of airflow control system for use in controlling temperature and airflow in an equipment room, according to an embodiment of the present invention;

FIG. 4 is a schematic illustration of another portion of the airflow control system, according to an embodiment of the present invention;

FIG. 5 is a schematic illustration of one example of a startup heater system, according to an embodiment of the present invention;

FIG. 6 is a schematic illustration of one example of a damper system which can be utilized to control air flow in the air conditioning system, according to an embodiment of the present invention;

FIG. 7 is a schematic illustration of one example of a humidifier system which can be used to increase moisture content in the air conditioning system, according to an embodiment of the present invention;

FIG. 8 is a schematic illustration of one example of an electrostatic particulars filter which can be used in the air-conditioning system, according to an embodiment of the present invention; and

FIG. 9 is a schematic illustration of one example of a processor based control system which may be used to control the functionality of the air-conditioning system, according to an embodiment of the present invention.

### DETAILED DESCRIPTION

In the following description, numerous details are set forth to provide an understanding of the present invention. However, it will be understood by those of ordinary skill in the art that the present invention may be practiced without these details and that numerous variations or modifications from the described embodiments may be possible.

The present invention relates to a technique by which air is conditioned for circulation through a space containing heat generating equipment, e.g. computer equipment, generally operated in a temperature controlled environment. The technique is useful in a variety of environments, such as cold environments. The external, ambient cold air is mixed with the internal hot air resulting from the heat producing equipment to produce an airstream within the desired temperature range for optimal operation of the equipment. Waste heat is exhausted to the external environment. In one embodiment, the technique utilizes an air conditioner module which provides a continuous volume of air at a controlled temperature to cool computer equipment or other instrumentation and to remove waste heat from that equipment without utilizing, for example, a heat pump inherent in traditional air conditioner systems. The air conditioner module also may be designed to control humidity.

The overall air conditioning system described herein also has an efficient design which requires substantially less energy to operate than conventional air conditioning systems. In many applications, the air conditioning system may be designed as a portable system which is transportable by, for example, a trailer to accommodate easy movement from one site to another. However, the system also can be incorporated into permanent or semi permanent structures to enable efficient conditioning of air in a variety of environments, including extremely cold environments.

Although the air conditioning system may be employed for operation in external ambient air temperatures over a substantial range, e.g. plus 20° C. down to minus 40° C. or lower, the system is particularly amenable to use in cold environments, e.g. 0° C. and below. Apart from possibly an inlet air control member, none of the operational components of the system is directly exposed to the cold air flow and thus the components do not need to be “arctic” grade components. The air conditioning system is designed to allow negative air pressure created within an equipment room/structure to draw in the cold, external ambient air for mixture with the internal air heated by the internal equipment, e.g. computer equipment. Accordingly, the system may be used in extreme, cold conditions, e.g. Arctic, Siberian, Alaskan conditions, and yet the system works up to an ambient air temperature of plus 20° C. without providing additional chiller/cooling units.

Depending on the specific application, optional components may be added to condition characteristics of the air other than temperature. For example, an optional low-energy humidifier may be added in certain cold environments to raise the moisture level in the dry air to a desired level. In another example, an optional electrostatic air filter may be added to reduce ingestion of particulates within the system.

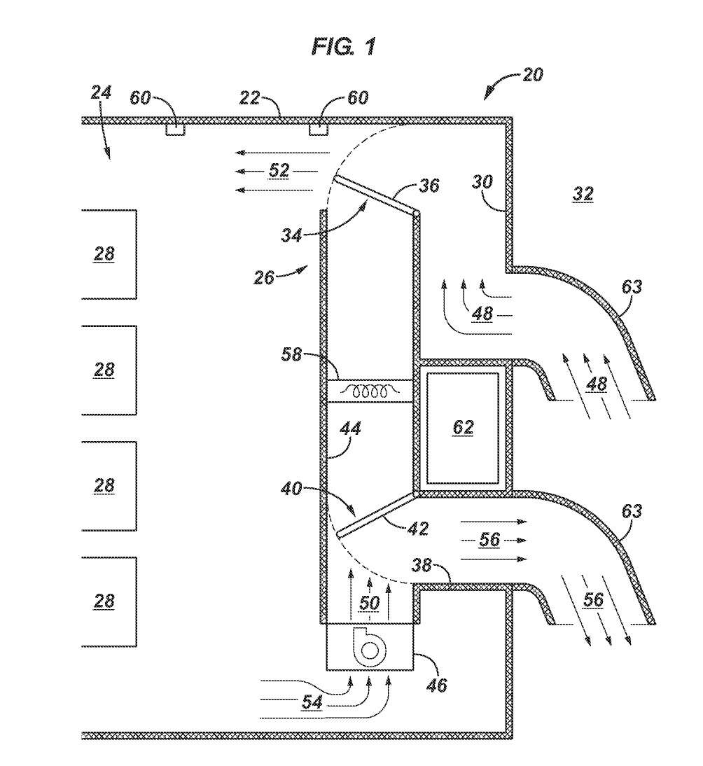

Referring generally to FIG. 1, an air conditioning system 20 is illustrated according to one embodiment of the present invention. As illustrated, air conditioning system 20 comprises a structure 22 having an equipment room 24 and an air management or conditioning section 26. Depending on the application, the equipment room and the air management section 26 may be a single unit or separate units which are joined. In some embodiments, the air management sections 26 are designed as modular sections which may be connected to the equipment room individually or in groups. The equipment room 24 contains heat generating equipment 28, such as computer equipment, for which the interior of equipment room 24 is maintained within a desired temperature range. For example, when operating computer equipment 28, substantial heat is generated but it often is desirable to maintain equipment room 24 within a temperature range of 18° C. to 22° C. and sometimes in a tighter range from 20° C. to 22° C. Additionally, many applications have a desired rate of drift held at less than 6° C. per hour.

In the embodiment illustrated in FIG. 1, air conditioning system 20 further comprises a cold air duct 30 which is connected between the equipment room 24 and an external environment 32. The external environment is an outdoor, ambient environment which, in many applications, may be extremely cold, e.g. 0° C. to minus 40° C. or colder. By way of example, the air-conditioning system 20 described herein may be designed to operate with environmental air at plus 20° C. or below. However, at temperatures above plus 20° C. ambient, a chiller or heat pump could be added in the outlet airstream. In the embodiment illustrated, a first flow controller 34 is positioned in the cold air duct 30 to control the amount of cold/ambient airflow from the external environment 32 into the equipment room 24. The first controller 34 may comprise a damper 36 or other suitable mechanism for selectively controlling airflow through the cold air duct 30.

Air conditioning system 20 also comprises an exhaust air duct 38 connected between the equipment room 24 and the external environment 32. A second flow controller 40 is positioned in the exhaust air duct 38 to control the amount of warm air flow from the equipment room 24 to the external environment 32. The second controller 40 also may comprise a damper 42 or other suitable mechanism for selectively controlling airflow through the exhaust air duct 38.

Additionally, a crossover duct 44 extends between the exhaust air duct 38 and the cold air duct 30. At least one of the flow controllers 34, 40 is positioned to also control the amount of airflow through crossover duct 44. In the embodiment illustrated, for example, both first flow controller 34 and second flow controller 40 are positioned to also control the amount of airflow through crossover duct 44. For example, the first flow controller 34 may move, e.g. pivot, between a position completely blocking flow through crossover duct 44 while maximizing flow through cold air duct 30 and a position completely blocking flow through cold air duct 30 while maximizing flow through crossover duct 44. Similarly, the second flow controller 40 may move, e.g. pivot, between a position completely blocking flow through crossover duct 44 while maximizing flow through exhaust air duct 38 and a position completely blocking flow through exhaust air duct 38 while maximizing flow through crossover duct 44. In at least some embodiments, the first flow controller 34 and second flow controller 40 may be designed to move in unison so that the amount of inflow and outflow is equalized. Also, the cold air duct 30 may be smaller in flow area than the exhaust air duct 38 to accommodate for the cooler, denser air entering from the external environment 32.

In the embodiment illustrated, a motive unit 46, such as a blower, is positioned to intake air from the equipment room 24 and to discharge the air into one or both of the exhaust air duct 38 and crossover duct 44 depending on the position of flow controller 40. As illustrated, blower 46 is used to create a negative pressure within equipment room 24 when exhausting air through duct 38. This negative pressure is used to draw in the cold air through cold air duct 30 from the external environment 32. As a result, the air conditioning system 20 is able to operate in extreme environments, e.g. arctic environments, in which external ambient temperatures down to minus 40° C. or below may exist. The designed use of negative pressure allows components potentially susceptible to the cold, e.g. blower 46, to be located on the “hot” side of the system, other than possibly inflow controller 34.

During normal operation, cold air from external environment 32 is drawn in through cold air duct 30, as represented by arrows 48. The airflow 48 flows past an at least partially open flow controller 34 and mixes with hotter air routed through crossover duct 44 as represented by arrows 50. The airflows 48 and 50 are mixed to create a mixed airflow within a desired temperature range, as represented by arrows 52, to cool the computer equipment 28 or other heat generating equipment within equipment room 24. As the air moves past equipment 28, the airflow is heated and drawn toward blower 46, as represented by arrows 54. Blower 46, in cooperation with flow controller 40, directs some air through crossover duct 44 (see arrows 50) and exhausts the remaining hot air through exhaust air duct 38, as represented by arrows 56. During startup or other cold operating periods, a heater element 58 may be employed along crossover duct 44 to heat the air flowing through crossover duct 44 to bring the equipment room 24 up to a minimum temperature level.

The temperature of the air introduced into equipment room 24, as represented by arrows 52, may be precisely controlled via one or more thermostats 60 located at the inlet to equipment room 24 and/or at other locations within the equipment room. In some embodiments, the one or more thermostats 60 are located in air management section 26 in the area where the mixed air flow is discharged, thus facilitating construction of the air management section 26 as a modular unit. The thermostats 60 (or other temperature measuring devices) may be coupled to a control system 62 which controls the position of first flow controller 34 and second flow controller 40 to adjust the amount of hot air flowing through crossover duct 44 for mixture with the external air entering through cold air duct 30. The control system 62 also may be designed to control heater element 58 to heat air flowing through crossover duct 44 during, for example, startup procedures. By way of example, control system 62 may comprise a computer-based control system which may be programmed to precisely control the temperature of air within the equipment room to maintain the room within a desired temperature range. However, other types of control systems may be employed, and at least one example of an alternate control system is described in greater detail below.

Depending on the environment and specific characteristics of a given application, the parameters of air conditioning system 20 may be adjusted. In one application example, air conditioning system 20 is a modular system designed to maintain an air supply to cool computer equipment within a temperature range from 18° C. to 22° C. (although some applications may require maintaining the temperature range between 18° C. and 20° C., between 20° C. and 22° C., or within other suitable ranges). Additionally, the system is sized to enable airflow through equipment room 24 in a range from approximately 3000 cubic feet per minute to approximately 18000 cubic feet per minute; and often in a range from 9000-18,000 cubic feet per minute which is sufficient for many applications. However, other applications may require different volumetric ranges of airflow. In the design illustrated, no motors, fans, blowers, or other parts of the system susceptible to cold are exposed to the direct, unmixed cold airflow through cold air duct 30. Use of a processor based computer control 62 enables ready adjustment of the control step size in adjusting, for example, movement of dampers 36 and 42. For example, the control step size may be relatively linear for the dampers and blower when environmental temperatures range from −40° C. up to plus 10° C. and the system would control the internal room temperature within a desired tolerance, e.g. plus/minus 2° C., with good response time. Above plus 10° C., the logic/computer control 62 may be adjusted to make be damper responses larger in response to changes in outside temperature and inside heat load. Thus, as the inside and outside temperatures become closer, the system response required to maintain the equipment room within the desired tolerance may require larger inputs/steps to the dampers 36, 42.

In some applications, the air in the equipment room 24 is preheated prior to startup of the heat generating equipment 28, e.g. computer equipment. The heater element 58 may be designed to enable sufficient warm airflow to raise equipment room 24 to a desired starting temperature at a desired rate, e.g. to a starting minimum temperature of 10° C. at a rate of no more than 10° C. per hour. The heating system also may be fitted with safety devices to prevent operation of heater element 58 without airflow. Additionally, heater element 58, in cooperation with control system 62, may be designed to provide low-power background heat and air circulation to keep the equipment room at a base temperature, e.g. no lower than 0° C., during periods of storage or transportation. In alternate configurations, this “background heater” also can be a separate unit which is not necessarily integrated into the air management section 26 of air conditioning system 20. Depending on the available energy, the background heater system, including air circulation, may be designed to operate below a certain power consumption level, e.g. below 2 kW of power consumption. In some environments, the air conditioning system 20 is designed with features to limit the ingress of snow, ice and water through cold air duct 30. For example, a downwardly directed housing 63 may be employed on one or both of the cold air duct 30 and exhaust air duct 38 to prevent the incursion of undesirable elements. A variety of filters also may be used to filter contamination from incoming airflow. The overall design and arrangement of components eliminates the need to use special, Arctic grade hardened components for the blower, control actuators, and other system components.

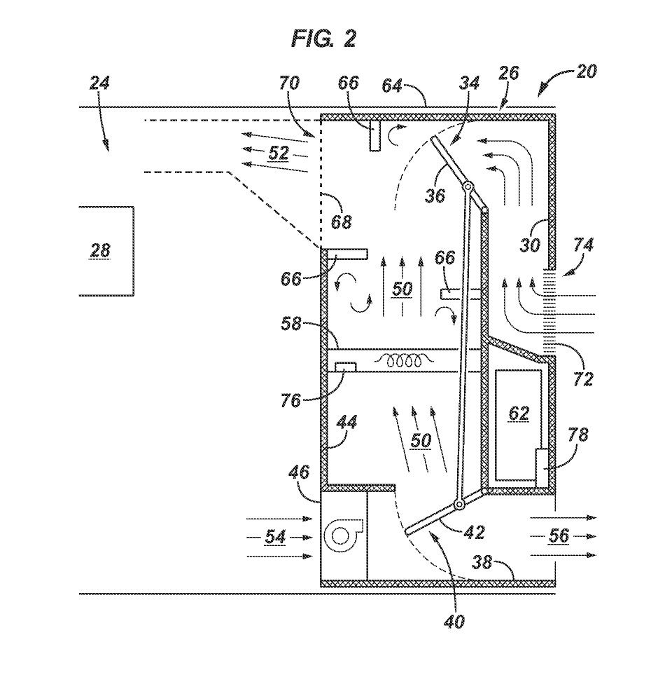

Referring generally to FIG. 2, another embodiment of air conditioning system 20 is illustrated. In this embodiment, air conditioning system 20 is a mobile unit mounted on a movable trailer 64, such as a trailer designed for transport by a tractor-trailer rig. The design in this embodiment and others may be a modular/self-contained design having the hot/cold ducts, startup heater, blower, and other components contained in one chamber or unit. The embodiment illustrated is similar to that illustrated in FIG. 1, and common reference numerals have been used to represent common components. In the embodiment illustrated in FIG. 2, however, a plurality of protrusions 66 are located in crossover duct 44 to cause turbulence in the airflow 50 moving through crossover duct 44. The turbulent airflow encourages mixing of the hotter air moving through crossover duct 44 with the colder air entering through cold air duct 30.

Additionally, a coarse grill 68, such as a coarse wire mesh grill, is located in a cool air exit 70 through which air moves from air management section 26 to equipment room 24. Grill 68 may be designed to further cause turbulence for better mixing of hot and cold air streams. Additionally, the grill 68 may be connected to the equipotential bonding of the equipment 28, e.g. computer equipment, to reduce or eliminate any electrostatic charge that has built up in the air. Optionally, a filter 72 may be located at an external intake 74 of cold air duct 30. In this particular embodiment, the flow controllers 34, 40 also are connected or geared together to enable closing and opening in unison under control of the thermostats 60 and control system 62. Additionally, heater module 58 comprises an air mass sensor 76, or other suitable sensor, to automatically cut power to heater module 58 when no airflow exists through crossover duct 44.

In general, the embodiments described above rely on creation of low/negative pressure in the equipment room 24 to draw cold air in through cold air duct 30. Additionally, the flow controllers 34, 40 may be precisely controlled to maintain the temperature within equipment room 24 within a desired, relatively narrow range. When both flow controllers are closed, all of the air is recirculated through equipment room 24 and there is no inlet of cold air or exhaust of hot air. When both flow controllers 34, 40 are partly open, there is some ingress of cold air caused by exhaust of hot air. The remaining hot air stream is directed through the crossover duct 44 and mixed with the cold air stream to provide an airflow to the equipment 28 within a desired temperature range, e.g. 18° C. to 20° C. When both flow controllers 34, 40 are fully open, no flow is allowed through crossover duct 44 and all the hot air is exhausted from the equipment room while all incoming air is cool air drawn entirely from the external environment 32.

In some embodiments, the air management section 26 may be independently transportable with respect to the equipment room 24. This allows one or more air management sections 26 to be assembled as modules for use with a corresponding equipment room to provide the desired airflow and cooling for equipment 28 within the equipment room 24. For example, if each air management section 26 is designed to deliver 3000 cubic feet of airflow per minute, then three separate modules may be fitted side-by-side for connection with a corresponding equipment room to yield a total of 9000 cubic feet per minute at full flow. An additional three of the modular air management sections 26 also could be coupled to another side of the equipment room to provide a total of 18,000 cubic feet per minute of airflow. This modular approach enables combination of different numbers of air management sections 26 with equipment rooms of a variety of sizes to provide an overall air-conditioning system 20 that is fully adjustable to accommodate a wide range of applications.

The air conditioning system 20 also may incorporate a variety of other features or arrangements. For example, the cold air duct 30 may be inclined, e.g. vertical, to draw cold air from the bottom upwards which avoids drawing water and snow directly into the system. The inclined orientation also enables gravity to help remove any material that enters up into housing 63 (see FIG. 1). By way of example, the housing 63 coupled with cold air duct 30 may slope downwardly at 16-20° or at another suitable angle to further prevent entry of undesirable elements. In many applications, the optional housing 63 may be removed for transport. Furthermore, the inlet to cold air duct 30 may be larger than normally required for a given airflow to reduce the inlet air flow velocity which also helps gravity act in removing snow or rain drawn into housing 63.

Blower 46 may be formed with a single blower unit or with multiple blower units such that failure of one unit does not affect operation of the other blower units. Additionally, the optional filter 72 may be designed with a large mesh size to avoid clogging with snow/ice while still preventing entry of large objects. Other types of filters also may be useful in certain environments and applications. One example of an alternate filter is an electrostatic particulate filter, an embodiment of which is described in greater detail below.

In a cold environment, the startup procedure for air conditioning system 20 may be important to avoid damage to sensitive equipment 28. In one sequence of operation example, an operator initially powers on the air conditioning system 20 at a control panel 78 (see FIG. 2). The control panel may provide a light to indicate the system is powered on but not sufficiently warm to start the computer equipment 28. Additionally, blower 46 is operated while both flow controller 34 and flow controller 40 are in a closed position to recirculate all airflow through crossover duct 44. If the ambient equipment room temperature is below 10° C. then the heater module 58 is turned on to start raising the air temperature in the equipment room 24. This condition also can be indicated by a light or other suitable indicator on control panel 78.

When the air temperature in equipment room 24 reaches 10° C., the heater module 58 may be switched to a thermostatically controlled maintenance mode for a desired time period, such as one hour. After the desired time period has passed and the computer equipment is sufficiently warmed, another indicator signals to the operator that it is safe to start the uninterruptible power supply and the computer equipment 28. After starting the computer equipment 28, the temperature in equipment room 24 continues to increase above 10° C. and the heater module 58 is disengaged. As the computer equipment 28 is operated, the temperature in the equipment room 24 continues to rise until it exceeds 18° C., at which time the flow controllers 34 and 40 are opened to enable the intake of external, cold air from external environment 32. The system may now be fully controlled by the thermostats 60 to open and close the flow controllers 34, 40 as necessary to maintain the temperature within the equipment room 24 in a desired range, e.g. 18° C. to 20° C. Although the startup sequence may be controlled manually as described above, the sequence also may be accomplished automatically via, for example, control system 62.

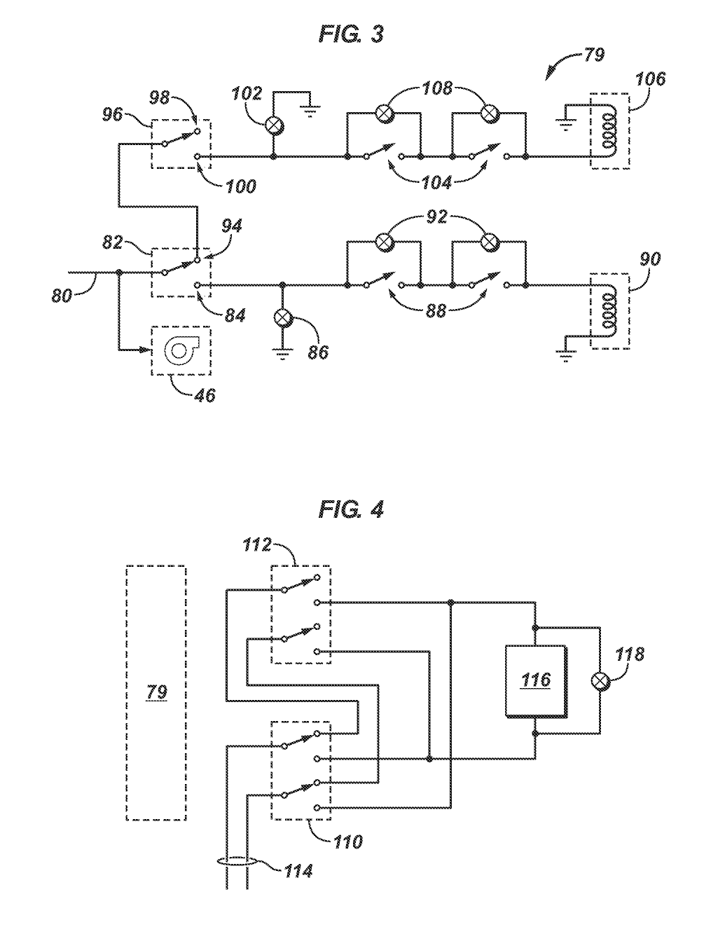

Referring generally to FIGS. 3 and 4, one embodiment of an alternate control system 62 for air conditioning system 20 is illustrated. In this embodiment, the control system comprises a simple, thermostatically controlled system which is capable of fairly simple diagnosis and maintenance. In FIG. 3, a low current flow controller, e.g. air damper, control logic 79 is illustrated. In this example, the control system may be supplied with 220V via an input 80. Power supplied via input 80 also powers blower contactor 46 which runs constantly independently of the thermostats.

As illustrated, input 80 is coupled to a cold thermostat 82 which closes against a contact 84 when the temperature in equipment room 24 drops below a desired range. The contact 84 is connected across an indicator light 86 which lights to indicate the equipment room is too cold. Additionally, the contact 84 is connected across a pair of flow controller limit switches 88 to a cold relay actuator coil 90. When supplied by current through contact 84, the cold relay actuator coil drives a relay which, in turn, drives a motor to close the flow controllers 34, 40, as described in greater detail with reference to FIG. 4. Closing the flow controllers 34, 40 causes more hot air to be directed through crossover duct 44, thereby increasing the temperature within equipment room 24. The flow controller limit switches 88 may include indicator lights 92 which alert an operator when the flow controllers are fully closed.

When the temperature rises, cold thermostat 82 closes against a second contact 94 and input 80 is coupled with a hot thermostat 96 which is illustrated as closed against a first contact 98. If the temperature in equipment room 24 rises above the desired range, hot thermostat 96 actuates and closes against a second contact 100. Contact 100 is connected across an indicator light 102 which lights to indicate the equipment room is too hot. Additionally, the contact 100 is connected across a pair of flow controller limit switches 104 to a hot relay actuator coil 106. When supplied by current through contact 100, the hot relay actuator coil 106 drives a relay which, in turn, drives a motor to open the flow controllers 34, 40, as described in greater detail with reference to FIG. 4. Opening the flow controllers 34, 40 allows more cold, external air to enter through cold air duct 30 which lowers the temperature within equipment room 24. The flow controller limit switches 104 may include indicator lights 108 which alert an operator when one or more of the flow controllers are fully open.

By way of example, the thermostats 82, 96 may comprise low hysteresis type thermostats in which the cold thermostat 82 is set to operate at 17° C. or 18° C. and the hot thermostat 96 is set to operate at 20° C. or 21° C. This provides for a 2° Celsius null range between them to prevent the system from “hunting”. As illustrated, the thermostats 82, 96 may be wired to prevent both relays from being energized at the same time even if the thermostat operating temperatures are incorrectly set. Additionally, the various indicator lights may comprise a variety of lights, e.g. neon type lamps, or other indicators.

In FIG. 4, one embodiment of the high current flow controller motor drive wiring is illustrated. In this example, a cold relay 110 and a hot relay 112 are connected to the low current air damper control logic 79 and to a high current DC power supply 114. The cold relay 110 and hot relay 112 are coupled with a motor 116, such as a reversible geared motor. By way of example, the high current DC power supply 114 may be connected to a permanent magnet reversible DC motor with a reduction gearbox. However, in other environments, motor 116 may comprise a reversible geared AC motor. In FIG. 4, relays 110, 112 are illustrated in their un-powered or default state. Operation of the cold relay 110 drives the motor 116 in one direction, and operation of the hot relay 112 drives motor 116 in the other direction. By way of example, the relays 110, 112 may be a double pole double throw (DPDT) type or another suitable type. Similar to the control thermostats 82, 96, the hot relay 112 may be fed power via the changeover contacts in the cold relay 110 so that it is not possible for both relays to feed power to the motor at the same time even if both relays are triggered. It should also be noted that an indicator light 118 may be provided to indicate the operational state of motor 116.

Referring generally to FIG. 5, an example of control logic that may be used in conjunction with heater element 58 is illustrated, although heater element 58 also may be controlled via a computer-based control system 62. In the illustrated embodiment heater element 58 does not need to be of large capacity/output, because it is not necessary, in most applications, to raise the temperature rapidly. In many applications, for example, it is desirable to raise the temperature in the equipment room no faster than 10° C. per hour. In the example illustrated in FIG. 5, a heater system 120 is designed to be fully autonomous once the overall air conditioning system 20 has been powered on. If for any reason, the temperature in equipment room 24 falls below a set level, e.g. 10° C., during normal operations, the heater element 58 is activated to restore the temperature to at least minimum startup levels.

As illustrated, heater system 120 is supplied with a low current control supply 122 which is coupled to an appropriate equipment room thermostat 60 and to a countdown timer 124 e.g. a one-hour countdown timer. The countdown timer 124 may be connected to an indicator or a plurality of indicators 126 designed to indicate when the equipment room 24 is at the desired temperature level, e.g. 10° C., and when the equipment room 24 has been held at a minimum of this temperature for a desired amount of time, e.g. one hour. The illustrated thermostat 60 also is connected to a heater power control relay 128, e.g. a DTDP type relay, across a heater demanded indicator 129 and a pair of emergency shutoffs 130, 132. Shutoff 130 is designed to shut off heater element 58 and to provide an indication of the shut off via indicator 134 when the heater in crossover duct 44 causes heating above a predetermined set level. Shutoff 132 is designed to shut off heater element 58 and to provide an indication of the shut off via indicator 136 when airflow through crossover duct 44 is stopped. Shutoff 132 may comprise an airflow switch with a simple micro-switch device having a small wind vane such that the contact closes when air movement at a required velocity ceases. During operation of heater element 58, current is supplied to the heater element via a high current heater supply 138 directed through heater power control relay 128.

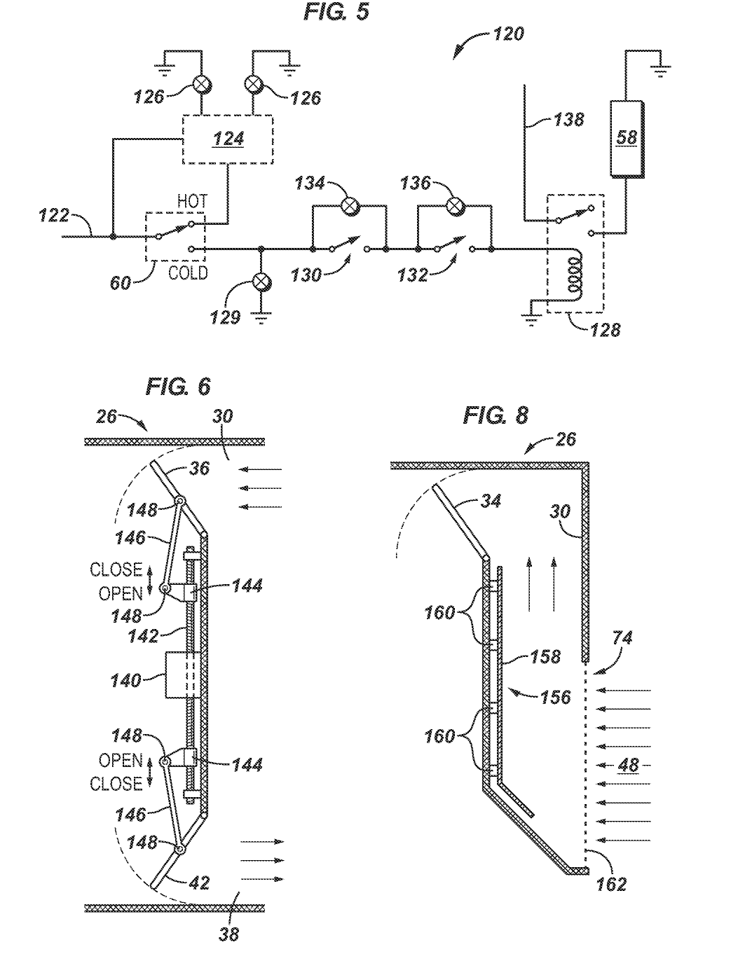

The flow controllers 34, 40 may comprise dampers 36, 42 which are independently controlled via an appropriate control system coupled to dedicated control motors. However, the flow controllers 34 also may be coupled together and operated in unison with a single device 140, such as a calibrated proportional control or stepper motor system. As a result, the flow controllers, e.g. dampers 36, 42, move in unison and by the same amount depending on commands from the thermostats 60. In FIG. 6, one example of a simple mechanical system is illustrated as able to operate dampers 36, 42 in unison via the single device 140, e.g. a single motor.

Device 140 is connected to a threaded shaft 142 and to a pair of threaded jockey members 144 disposed on opposite sides of device 140. The shaft 142 has left-hand threads on one side of device 140 and right-hand threads on the other side of device 140. With each end of the shaft 142 having opposite threads with respect to the other, the dampers 36, 42 simultaneously close or simultaneously open when shaft 142 is rotated by device/motor 140. Accordingly, the threaded jockey members 144 either move toward each other or away from each other when shaft 142 is rotated in one direction or the other. Each threaded jockey member 144 also is connected to a corresponding damper 36, 42 via a link 146 having a pivot connection 148 at each of its ends. The dampers 36, 42 may be designed to close against a wall of the air management section 26 at a slight angle to enable easier opening actuation via link 146. Although device 140 may have a variety of forms, one example is a reversible motor with a reduction gearbox.

Depending on the environment, exterior temperature, and equipment 28, air conditioning system 20 also may incorporate a low energy humidifier. By using waste heat directed to the external environment 32 through exhaust air duct 38, snow or ice can be melted. The melt-water is turned into a very fine mist by, for example, an atomizer which introduces moisture into the warm air stream flowing through, for example, crossover duct 44 to vaporize the moisture. By way of example, the atomizer may be a mechanical pump and high-pressure nozzle, or an ultrasonic atomizer may be particularly useful in some embodiments.

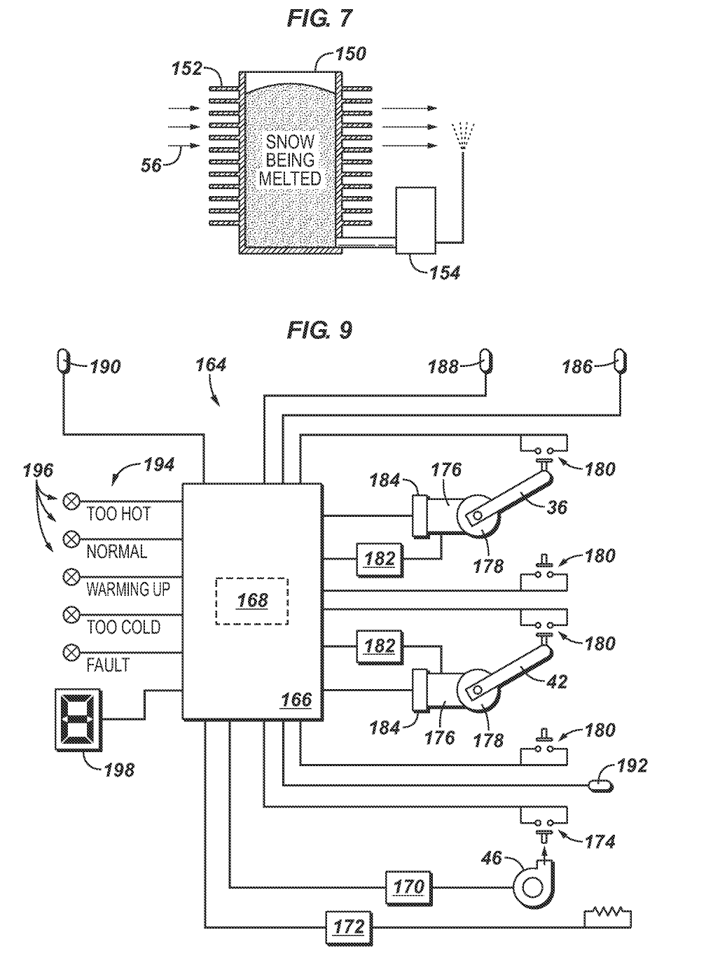

As illustrated in FIG. 7, snow or ice may be placed in a container 150 fitted with a finned heatsink 152 to facilitate the transfer of heat from the air stream 56 to the container 150. The warm airflow melts the snow/ice, and the resulting water is fed to an atomizer 154 which atomizes the water and introduces the fine mist into a hot air stream, such as the air steam flowing through crossover duct 44. The atomizer 154 may be controlled by control system 62 or by another suitable control system based on readings obtained from a humidistat located in the equipment room 24. Additionally, a water sensor or float switch may be placed in container 150 to stop the atomizer 154 if no water remains in container 150.

Another optional component which may be incorporated into air conditioner system 20 is an electrostatic particulates filter 156, as illustrated in FIG. 8. In this embodiment, the electrostatic particulates filter 156 comprises a positively charged plate 158 mounted along an interior of the cold air duct 30. The positively charged plate 158 may be mounted to a wall of cold air duct 30 via insulators 160 to enable attraction of particulates and water droplets to the charged plate 158. The external intake 74 may be relatively large compared to the rest of the cold air duct 30 to reduce air velocity. The incoming cold air 48 passes through a mesh grille 162 which removes any positive charge from the inflow or even causes it to be slightly negative. The mesh grille may be grounded or slightly negatively charged. Additionally, the mesh grille may be heated to melt any buildup of snow/ice.

The inflow of cold air is then routed past the positively charged metal plate 158 which attract particulates and water droplets. The plate 158 also may be heated to discourage ice from forming along the interior of the cold air duct 30. Any resulting water is drained from the bottom of the cold air duct 30.

In some applications, control over the overall operation of system 20 is accomplished by forming control system 62 as a processor based system 164, an example of which is illustrated in FIG. 8. In this example, the processor based system 164 comprises a microcontroller 166 having, for example, a circuit board incorporating a microprocessor 168 with an embedded control program designed to control the operation of the overall air conditioning system.

The blower 46 draws air from the cabin/computer equipment room 24 and directs the air towards the control flap 42. In this example, the blower 46 is under the control of microcontroller 166 via a three-phase motor rated contactor switch 170 which, in some embodiments, may be designed to suit 3 phase 400V fan motor requirements. Heater 58 also is controlled by microcontroller 166 and coupled to the microcontroller through a contactor 172. The heater element 58 is positioned in the recirculation air path to provide initial startup heating of the equipment cabin interior. An over temperature protection device may be built into the heating element 58 to protect the heating element from insufficient airflow. Additionally, an airflow switch 174 is mounted in the air flowing out of the blower 46. The airflow switch 174 is designed to provide data to microcontroller 166 regarding whether the blower 46 is operating and generating sufficient airflow.

In this embodiment, the position of control flap 42 is controlled by a motor 176 and a cooperating gearbox 178. As described above, control flap 42 controls the proportion of warm air which is exhausted to the outside environment relative to the amount returned to the recirculation air path. Limit switches 180 may be positioned to inform the microcontroller 166 when the control flap 42 has reached the fully open, i.e. all air exhausted to the environment, or fully closed, i.e. all air returned to the recirculation system, positions.

Similarly, control flap 36 is controlled by another motor 176 and cooperating gearbox 178. As described above, control flap 36 controls the proportion of external cold air which is drawn into the air circulation system relative to the amount received from the air recirculation path. Again, limit switches 180 may be positioned to inform the microcontroller 166 when the control flap 36 has reached the fully open, i.e. all air drawn from the external environment, or fully closed, i.e. all air drawn from the recirculation system, positions. Additionally, the control flaps 36 and 42 may electronically track each other.

Each of the motors 176 may be coupled with the microcontroller 166 through a motor drive 182. Additionally, feedback may be provided by each motor 176 to the microcontroller 166 through a tachometer 184 or other suitable device. A variety of motors and gearboxes may be employed. However, one example of an in-line motor and gearbox is the Mclennan M66 series motor with fitted encoder and an IP57 250:1 gearbox in which the drive to the control flap comprises a toothed belt. Another example is a worm geared motor, such as the Parvalux P11WS series motor with fitted tacho. In this example, the drive to the control flap would be directly from the output shaft, although additional mechanical linkages could be employed.

In the example illustrated in FIG. 9, data is provided to microcontroller 166 by an inlet temperature sensor 186 which monitors the cold air entering the system from the external environment. Additional data is provided to the microcontroller 166 by a mixed temperature sensor 188 which monitors the temperature of air passing into the equipment room/cabin 24. Data also may be provided to microcontroller 166 from an equipment room temperature sensor 190 which is positioned in equipment room 24 to monitor the temperature. An exhaust temperature sensor 192 also provides data to microcontroller 166 on the temperature of air being returned to the surrounding environment. A visual mode indicator 194 may be formed with a plurality of LEDs 196 and a fault code display 198 to provide a visual indication of operating status. However, a variety of other indicators, including output display screens, may be used to provide status information.

The microcontroller 166 may be programmed to carry out various sequences of operation with respect to system startup and shutdown. As discussed above, procedural sequences may be designed to initiate startup of the heater element and other system components. Depending on the ambient temperatures, environmental conditions, types of heaters, control systems, airflow controllers, blowers and other components, the sequences of operation may be optimized for the given application. Similarly, the firmware for processor based system 164 may be designed in a variety of forms to accommodate many environments and applications. As environmental conditions change, the specific operation of the firmware may be optimized by, for example, adjusting the delay parameters used in the maintenance mode and operational mode control loops to achieve an appropriate speed and precision with respect to response of the controlled components.

Additionally, the processor based control system 164 may be housed in a suitable enclosure. In some embodiments, the enclosure may be designed to incorporate the microcontroller 166, the blower and heater contactors 170, 172, the motor drives 182, and connections for the temperature sensors, airflow sensors, and limit switches. In some embodiments, the enclosure may have an IP rating of minimum IP66 to enable the control system 164 to be detached from the structure 22 and stored outside.

The embodiments discussed above are just a few of the configurations and procedures that can be used to condition air in an energy efficient manner in a cold environment. However, the energy efficient approach may be employed in a variety of environments, including warmer environments up to, for example, plus 20° C. to realize energy savings of 30 percent or more (with the addition of a chiller or heat pump, the system also may be employed in environments with temperatures above plus 20° C.). As described above, the overall air conditioning system 20 may be designed with equipment room 24, heat generating equipment 28, and air management section 26 combined in a single unit. This single unit, however, may be constructed as a transportable unit to enable movement from one site to another. Alternatively, the air conditioning system 20 may have an independent equipment room 24 and air management section 26 formed as modular units which may be selectively connected together. In some embodiments, a plurality of the air management sections 26 may be constructed as modular units for combination with a single equipment room structure. In some applications, the mode of operation/logic is specifically designed for an intended use case with integration of startup heater to raise the system temperature to a desired minimum startup temperature after storage or camp move. Specific time delays may be built in to acclimate the system, drive off condensation, and otherwise prepare the system as desired for the intended use case.

Depending on the environment and the specifics of a given application, the air conditioning system 20 may be designed in a variety of sizes, configurations and capacities. Some of the embodiments are sized for mounting on a conventional trailer for transport along existing roadways. Additionally, a variety of components may be added or incorporated into the overall air conditioning system to provide conditioning and/or monitoring features which facilitate control over the condition of the air used to cool computer equipment or other heat generating equipment. Additionally, the air conditioning system may be controlled by a computer-based control system or by a variety of other control systems, such as those described above.

Although only a few embodiments of the present invention have been described in detail above, those of ordinary skill in the art will readily appreciate that many modifications are possible without materially departing from the teachings of this invention. Accordingly, such modifications are intended to be included within the scope of this invention as defined in the claims.

What is claimed is:

1. A system to maintain a controlled temperature, comprising:
an equipment room having computer equipment generating substantial heat when operated;
a cold air duct connected between the equipment room and an external environment; and a first flow controller positioned in the cold air duct to control the amount of airflow from the external environment into the equipment room;
an exhaust air duct connected between the equipment room and the external environment; and a second flow controller positioned in the external air duct to control the amount of airflow from the equipment room to the external environment;
a crossover duct extending between the exhaust air duct and the cold air duct, at least one of the first and second flow controllers being positioned to control flow through the crossover duct; and
a blower disposed to cause circulation of air through at least one of the exhaust air duct and the crossover duct to maintain the computer equipment room at a desired temperature.

2. The system as recited in claim 1, further comprising an automated controller coupled to the first and second flow controller to control the desired amount of air flow through each of the cold air duct, exhaust air duct and the crossover duct, wherein the equipment room, cold air duct, exhaust air duct, crossover duct, and s blower are all in a self-contained transportable unit.

3. The system as recited in claim 1, wherein a negative pressure in the equipment room is used to draw air in through the cold air duct.

4. The system as recited in claim 1, wherein the equipment room is maintained in a temperature range of 18° C. to 22° C.

5. The system as recited in claim 1, wherein airflow through the equipment room is scalable.

6. The system as recited in claim 1, wherein the first and second flow controllers comprise thermostatically controlled dampers.

7. The system as recited in claim 1, wherein the cold air duct is smaller in cross-sectional area than the exhaust air duct to allow for a difference in air density between hot and cold air.

8. The system as recited in claim 1, further comprising a plurality of protrusions to mix air from the cold air duct and the crossover duct prior to flowing past the computer equipment.

9. The system as recited in claim 1, further comprising a wire mesh grille through which air flows prior to the computer equipment.

10. The system as recited in claim 1, further comprising a filter positioned to filter air flowing into the cold air duct from the external environment.

11. The system as recited in claim 1, wherein the first and second flow controllers move in unison.

12. The system as recited in claim 1, wherein the first and second flow controllers are computer controlled.

13. The system as recited in claim 1, further comprising a startup heater to bring the equipment room to an initial start temperature.

14. The system as recited in claim 1, further comprising a humidifier to raise the humidity of air flowing into the equipment room.

15. A system for controlling a room temperature in a cold environment, comprising:
a portable structure comprising an air management section having:
a cold air duct extending from an external environment for connection to an equipment room, wherein the cold air duct is designed to enable negative pressure in the equipment room to draw air through the cold air duct from the external environment;
an exhaust air duct extending from an external environment for connection to the equipment room;
a crossover duct to recirculate air from the exhaust air duct to the cold air duct;
a flow control system to control the amount of airflow through the cold air duct, exhaust air duct, and crossover duct; and
a motive unit positioned to intake air from the equipment room and to exhaust air into at least one of the exhaust air duct and crossover duct.

16. The system as recited in claim 15, further comprising the equipment room having heat generating equipment which operates in a controlled temperature range.

17. The system as recited in claim 16, wherein the flow control system comprises a first damper placed in the cold air duct and a second damper placed in the exhaust air duct, the first and second dampers being positioned to also affect airflow through the crossover duct.

18. A method of conditioning air, comprising:
routing cool air from an external environment into a computer equipment room through a cold air duct;
discharging warm air from the computer equipment room to the external environment through an exhaust air duct;
flowing warm air from the exhaust air duct to the cold air duct through a crossover duct to condition the temperature of the air flowing in from the external environment; and
imparting airflow through the computer equipment room via a motive unit without exposing the motive unit to the external environment.

19. The method as recited in claim 18, further comprising controlling the amount of airflow into the cold air duct, the exhaust air duct, and the crossover duct with a pair of dampers.

20. The method as recited in claim 18, wherein discharging comprises moving air from the computer equipment room to the external environment with a blower.

21. The method as recited in claim 18, wherein imparting comprises drawing air through the cold air duct with a negative pressure created in the computer equipment room.

22. The method as recited in claim 18, wherein routing comprises routing air from the external environment at a temperature less than 20 ° C.

23. The method as recited in claim 22, further comprising maintaining the computer equipment room at a temperature range from 18° C. to 22° C.
